(19) United States
(12) Patent Application Publication
(10) Pub. No.: US 2025/0349682 A1
(43) Pub. Date: Nov. 13, 2025

(54) DUAL-SIDED MOLD GRID ARRAY MODULE HAVING FLAT BOTTOM

(71) Applicant: SKYWORKS SOLUTIONS, INC., Irvine, CA (US)

(72) Inventors: Yi LIU, San Diego, CA (US); Julianna M. MARKOVSKY, Costa Mesa, CA (US); Sergio Joaquin GONZALEZ, Irvine, CA (US); Ki Wook LEE, Irvine, CA (US); Anthony James LOBIANCO, Irvine, CA (US)

(21) Appl. No.: 19/203,038

(22) Filed: May 8, 2025

Related U.S. Application Data
(60) Provisional application No. 63/645,833, filed on May 10, 2024.

(51) Int. Cl. H01L 23/498; H01L 23/31; H01L 25/04

(52) U.S. Cl. CPC H01L 23/49816; H01L 23/3135; H01L 25/04

(57) ABSTRACT

A dual-sided mold grid array module can include a substrate having a mounting side and a plurality of solder structures implemented thereon, with each solder structure having a shape that is different from its original shape when originally formed. The module can further include a mold structure implemented on the mounting side of the substrate and having a surface, such that each solder structure is surrounded by a respective portion of the mold structure having a shape formed based on the original shape of the solder structure, such that a gap is provided between the shape of the respective portion of the mold structure and the solder structure at or near the surface of the mold structure.

### CROSS-REFERENCE TO RELATED APPLICATION(S)

This application claims priority to U.S. Provisional Application No. 63/645,833 filed May 10, 2024, entitled DUAL-SIDED MOLD GRID ARRAY MODULE HAVING FLAT BOTTOM, the disclosure of which is hereby expressly incorporated by reference herein in its respective entirety.

### BACKGROUND

### Field

The present disclosure relates to packaged radio-frequency (RF) modules having flat bottom.

### Description of the Related Art

Many radio-frequency (RF) modules are implemented in a packaged format that includes a packaging substrate and components mounted on either or both sides of the packaging substrate. A mold structure can be provided on either or both sides of such a packaging substrate, and conductive mounting features can be provided on one side of such an assembly to allow mounting of the resulting module onto a circuit board.

### SUMMARY

In accordance with a number of implementations, the present disclosure relates to a packaged module that includes a substrate having a mounting side, and a plurality of solder structures implemented on the mounting side of the substrate, with each solder structure having a shape that is different from its original shape when originally formed. The packaged module further includes a mold structure implemented on the mounting side of the substrate and having a surface, such that each solder structure is surrounded by a respective portion of the mold structure having a shape formed based on the original shape of the solder structure, such that a gap is provided between the shape of the respective portion of the mold structure and the solder structure at or near the surface of the mold structure.

In some embodiments, packaged module can further include a mold structure implemented on a non-mounting side of the substrate opposite from the mounting side. In some embodiments, packaged module can further include one or more components mounted on either or both of the non-mounting side and mounting side of the substrate, with at least some of the one or more components including a die, such as a semiconductor die, configured to provide radio-frequency functionality. In some embodiments, at least one component can be mounted on each of the non-mounting side and mounting side of the substrate.

In some embodiments, the surface of the mold structure can be flat. The shape of each solder structure can include a profile at or near the surface of the mold structure, with the profile resulting from a re-shaping operation that re-shapes the original shape of the solder structure to the shape while the solder structure is surrounded by the mold structure. The re-shaping operation can include application of energy to melt some or all of the solder structure to allow the solder structure to be formed into the shape while the solder structure is surrounded by the mold structure.

In some embodiments, each solder structure can include a flat surface at or near the flat surface of the mold structure, with the flat surface of the solder structure resulting from removal of a portion of the profile of the solder structure. The flat surface of the mold structure can be substantially co-planar with the flat surface of the solder structure. The flat surface of the mold structure and the flat surface of the solder structure can be formed from a removal process, such as a grinding process, that removes respective portions of the mold structure and solder structure.

In some embodiments, the solder structure can have a melting point and the mold structure can have a melting point that is higher than the melting point of the solder structure.

In some embodiments, the original shape of the solder structure can be based on formation without the presence of the mold structure, and the shape of the solder structure can be based on formation with the presence of the mold structure. The original shape of the solder structure can include a solder ball shape.

In some implementations, the present disclosure relates to a method for manufacturing a packaged module. The method includes providing or forming a substrate having a mounting side and a non-mounting side, implementing a plurality of solder structures on the mounting side of the substrate such that each solder structure has an original shape, and processing the mounting side of the substrate to include implementing a mold structure on the mounting side of the substrate such that the mold structure has a surface and an engagement shape around each solder structure based on the original shape of the solder structure, and such that the solder structure includes an exposed surface with respect to the surface of the mold structure. The method further includes re-shaping each solder structure such that a gap is provided between the respective engagement shape of the mold structure and the re-shaped solder structure at or near the surface of the mold structure.

In some embodiments, the processing of the mounting side of the substrate can further include mounting one or more components on the mounting side of the substrate prior to the implementing of the mold structure.

In some embodiments, the method can further include processing the non-mounting side of the substrate, including mounting one or more components on the non-mounting side of the substrate and forming a mold structure on the non-mounting side of the substrate to encapsulate some or all of the one or more components.

In some embodiments, the surface of the mold structure can be flat. The re-shaping can include applying energy to melt some or all of the solder structure while the solder structure is surrounded by the mold structure. The re-shaping can further include removing a portion of each solder structure to provide a flat surface for the re-shaped solder structure with respect to the flat surface of the mold structure. The flat surface of the mold structure can be substantially co-planar with the flat surface of the re-shaped solder structure.

In some embodiments, the flat surface of the mold structure and the flat surface of the re-shaped solder structure can be formed from a removal process that removes respective portions of the mold structure and re-shaped solder structure. The removal process can include a grinding process.

In some embodiments, the method can further include processing the non-mounting side of the substrate, including mounting one or more components on the non-mounting side of the substrate and implementing a mold structure on the non-mounting side of the substrate. In some embodiments, the processing of the non-mounting side of the substrate can be performed prior to the processing of the mounting side of the substrate.

In some embodiments, the substrate can be a unit among a plurality of units arranged in an array format on a panel, such that some or all of the steps can be performed for each unit while in the array format. The method can further include singulating the units in the array format to provide a plurality of singulated units. The method can further include forming a shielding layer to each of some or all of the singulated units.

According to some implementations, the present disclosure relates to a system for manufacturing packaged modules. The system includes a panel handling component configured to handle a panel having an array of units, with each unit having a substrate that includes a mounting side and a non-mounting side. The system further includes an assembly component configured to implement a plurality of solder structures on the mounting side of the substrate of each unit such that each solder structure has an original shape. The system further includes one or more components for processing the mounting side of the substrate, with the processing including implementing a mold structure on the mounting side of the substrate of each unit such that the mold structure has a surface and an engagement shape around each solder structure based on the original shape of the solder structure, and such that the solder structure includes an exposed surface with respect to the surface of the mold structure. The system further includes a re-shaping component configured to re-shape each solder structure such that a gap is provided between the respective engagement shape of the mold structure and the re-shaped solder structure at or near the surface of the mold structure.

In some embodiments, the system can further include a singulation component configured to singulate an assembly resulting from the process operations into a plurality of individual packaged modules. In some embodiments, the system can further include a deposition component configured to form a shielding layer to each individual packaged module.

In some embodiments, the one or more components can include a panel mold component configured to form the mold structure on the mounting side of the substrate of each unit. The one or more components can further include a panel grind component configured to form the surface of the mold structure and to provide the exposed surface of the solder structure with respect to the surface of the mold structure.

In some embodiments, the re-shaping component can be configured to provide energy to the solder structures of each unit to sufficiently melt to form the respective re-shaped solder structures. In some embodiments, the energy provided to the solder structures can include heat.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIGS. 1A to 1D show examples of assemblies before formation of a gapped configuration.

FIGS. 2A to 2D shows assemblies corresponding to FIGS. 1A to 1D with each having a gapped configuration.

FIG. 3 shows an enlarged view of an assembly that is similar to the assembly of FIG. 2A.

FIG. 4 shows an example of a configuration where a portion of an altered solder structure has been removed to provide a new surface.

FIG. 5 shows another example of a configuration where a portion of an altered solder structure has been removed to provide a new surface.

FIG. 6 shows that in some embodiments, the thickness of a mold structure can be changed to provide a desired thickness.

FIGS. 7A to 7I show various stages of a process that can be implemented to manufacture a packaged module having one or more features as described herein.

FIG. 8A shows an enlarged view of a portion indicated in FIG. 7G.

FIG. 8B shows an enlarged view of a portion indicated in FIG. 7H.

FIG. 8C shows a sectional photograph of an enlarged view that is similar to the enlarged view of FIG. 8B.

FIG. 8D shows an enlarged view of a portion indicated in FIG. 7I.

FIGS. 9A to 9C show example stages of fabrication where multiple units are processed while in an array format and then singulated to provide multiple packaged units.

FIGS. 10A to 10I show side views of various stages of a process that can be utilized to form an array of process units in a panel format similar to the example of FIG. 9B, starting with a substrate panel similar to the example of FIG. 9A.

FIG. 10J shows that in some embodiments, the assembly of FIG. 10I can be singulated to provide a plurality of individual units.

FIG. 11 shows a packaged module having one or more features as described herein, where such a packaged module can be similar to the assembly of FIG. 7I or an individual unit of FIG. 10J.

FIG. 12 shows a packaged module that is similar to the packaged module of FIG. 11, but with a conformal shielding layer formed from electrically conductive material that covers non-mounting sides of the packaged module.

FIG. 13 shows a flat-bottom module having one or more features as described herein, similar to the examples of FIGS. 71, 11 and 12, where one or more components is/are mounted on the upper side of a packaging substrate, and one or more components is/are mounted on the lower side of the packaging substrate.

FIG. 14A shows a mounted configuration where the flat-bottom module of FIG. 13 is mounted onto a circuit board.

FIG. 14B shows an enlarged view of a portion indicated in FIG. 14A.

FIG. 15 shows that in some embodiments, one or more features of the present disclosure can be implemented in a module packaging system.

### DETAILED DESCRIPTION OF SOME EMBODIMENTS

The headings provided herein, if any, are for convenience only and do not necessarily affect the scope or meaning of the claimed invention.

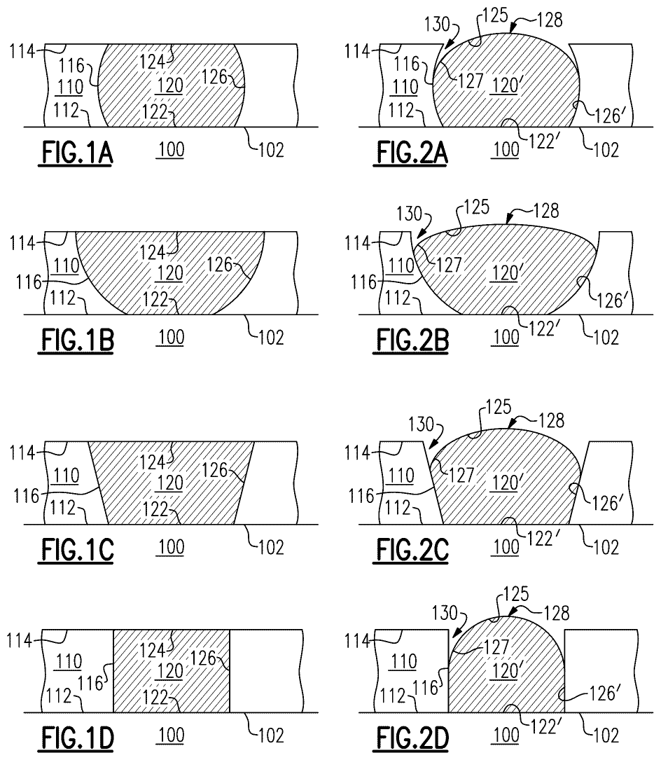

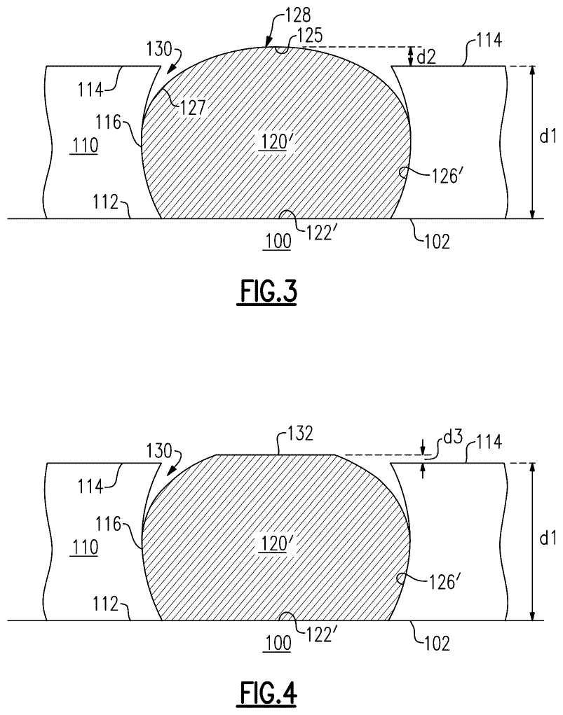

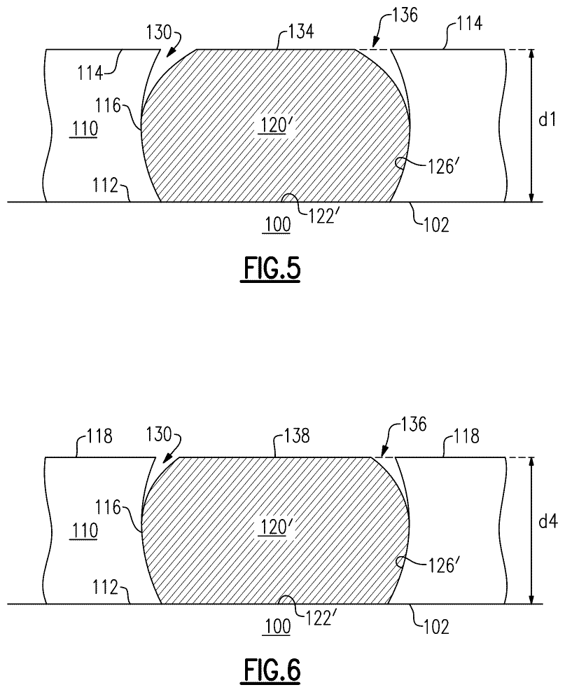

Disclosed herein are examples related to a conductive mounting feature and a surrounding structure, where the conductive mounting feature is formed to provide a desirable gap between it and the surrounding structure. FIGS. 1A to 1D show examples of assemblies before formation of such a gapped configuration, and FIGS. 2A to 2D shows corresponding assemblies each having a gapped configuration.

For example, FIG. 1A shows a conductive mounting feature 120 implemented to have a surface 122 engaged with a surface 102 of a packaging substrate 100. For the purpose of description, such a conductive mounting feature can be, for example, a solder-material structure such as a solder ball; however, it will be understood that one or more features of the present disclosure can also apply to other types of conductive mounting features.

In the example of FIG. 1A, a mold structure 110 is shown to be implemented over the surface 102 of the packaging substrate 100 so as to have one side (112) engaged with the surface 102 and encapsulate the side of the solder ball 120. Accordingly, an inward-facing wall 116 of the mold structure 110 is shown to engage an outward-facing wall 126 of the solder ball 120 without any gap therebetween.

In the example of FIG. 1A, the solder ball 120 is shown to have an exposed surface 124, and such an exposed surface can be substantially co-planar with an exposed side 114 of the mold structure 110. Configured as such, the exposed side 114 of the mold structure 110 and the exposed surface 124 of the solder ball 120 can form a flat mounting side of a packaged module having the packaging substrate 100. Examples related to how such a flat mounting configuration can be achieved are described herein in greater detail.

It is noted that in some mounting applications, the flat nature of the mounting side of the example of FIG. 1A can result in difficulties and reliability issues. To address some or all of such mounting difficulties and reliability issues, a gap space can be provided around the periphery of the solder ball. For example, laser ablation can be utilized to remove material from the mold structure to provide a gap between the mold structure and the periphery of the solder ball which remains generally unchanged.

Described herein are examples of how a gap can be formed between a solder structure and a corresponding mold structure by altering the solder structure. In some embodiments, the mold structure can remain generally unchanged during the change in the solder structure.

FIG. 2A shows an example of an altered solder structure 120′ relative to a generally unchanged mold structure 110. In some embodiments, such an altered solder structure can result from melting of some or all of the solder ball 120 of FIG. 1A so as to provide an altered shape. Such an altered shape can include a profile 128 having a side portion 127 and an upper portion 125 (when viewed as shown in FIG. 2A) resulting from the shape-altering operation (e.g., melting operation). In some embodiments, the altered profile 128 can be at least in part due to a surface tension of the solder material during the melting operation.

Configured in the foregoing manner, one can see that the side portion 127 of the altered solder structure 120′ is now separated from the inward-facing wall 116 of the mold structure 110. Further, the side and upper portions 127, 125 of the altered solder structure 120′ can have a curved profile at least in part due to the surface tension of the solder material during the melting operation.

It is noted that in some embodiments, the mold structure 110 can be configured to substantially retain its shape during the melting operation that results in the altered solder structure 120′. For example, the mold structure 110 can have a melting temperature that is higher than the melting temperature that provides the altered solder structure 120′.

In the example of FIG. 2A, the altered solder structure 120′ is shown to include a lower side portion 126′ (when viewed as shown) that is engaged to the respective portion of the inward-facing wall 116 of the mold structure 110. In some embodiments, such an engagement of the lower side portion 126′ of the altered solder structure 120′ and the inward-facing wall 116 of the mold structure 110 can result from the engagement remaining during the solder material melting operation, engagement being broken and being re-formed during the solder material melting operation, or some combination thereof.

In the example of FIG. 2A, substrate-engaging side 122′ of the altered solder structure 120′ is shown to be substantially engaged to the surface 102 of the packaging substrate 100. In some embodiments, such an engagement of the substrate-engaging side 122′ of the altered solder structure 120′ and the surface 102 of the packaging substrate 100 can result from the engagement remaining during the solder material melting operation, engagement being at least partially broken and being re-formed during the solder material melting operation, or some combination thereof.

In the example of FIG. 2A, the altered solder structure 120′ is shown to provide a gap 130 between the side portion 127 of the altered solder structure 120′ and the inward-facing wall 116 of the mold structure 110. It is noted that in the example of FIG. 2A, the portion of the inward-facing wall 116 of the mold structure 110 defining the gap 130 can include an overhang (e.g., relative to a vertical portion of the inward-facing wall 116) that would not be present in a configuration resulting from other gap-forming operations such as a laser ablation operation. It is also noted that in the example of FIG. 2A, the side portion 127 of the altered solder structure 120′ having a surface tension-induced profile would not be present in a configuration resulting from other gap-forming operations such as a laser ablation operation.

For the example of FIG. 2A, the original solder ball 120 of FIG. 1A has a shape such that its widest lateral dimension is between the lower and upper sides 112, 114 of the mold structure 110 (when viewed as shown in FIG. 1A). In some embodiments, an original solder ball can be configured such that its widest lateral dimension is coplanar with one of the lower and upper sides 112, 114 of the mold structure 110.

For example, FIG. 1B shows a conductive mounting feature 120 (e.g., a solder ball) implemented to have a surface 122 engaged with a surface 102 of a packaging substrate 100. In some embodiments, such a solder ball and a corresponding mold structure 110 can be implemented so that an inward-facing wall 116 of the mold structure 110 is shown to engage an outward-facing wall 126 of the solder ball 120 without any gap therebetween, similar to the example of FIG. 1A.

In the example of FIG. 1B, the solder ball 120 is shown to have an exposed surface 124, and such an exposed surface can be substantially co-planar with an exposed side 114 of the mold structure 110. Configured as such, the exposed side 114 of the mold structure 110 and the exposed surface 124 of the solder ball 120 can form a flat mounting side of a packaged module having the packaging substrate 100. In some embodiments, such co-planar surfaces 114, 124 of the mold structure and solder ball 120, where the lateral dimension of the exposed surface 124 is the largest for the solder ball 120, can be achieved similar to the example of FIG. 1A, but with additional removal of materials.

FIG. 2B shows an example of an altered solder structure 120′ relative to a generally unchanged mold structure 110. In some embodiments, such an altered solder structure can result from melting of some or all of the solder ball 120 of FIG. 1B so as to provide an altered shape. Such an altered shape can include a profile 128 having a side portion 127 and an upper portion 125 (when viewed as shown in FIG. 2B) resulting from the shape-altering operation (e.g., melting operation). In some embodiments, the altered profile 128 can be at least in part due to a surface tension of the solder material during the melting operation.

Configured in the foregoing manner, one can see that in the example of FIG. 2B, the altered solder structure 120′ provides a gap 130 between the side portion 127 of the altered solder structure 120′ and the inward-facing wall 116 of the mold structure 110. It is noted that in the example of FIG. 2B, the portion of the inward-facing wall 116 of the mold structure 110 defining the gap 130 does not include an overhang, since the upper side 114 of the mold structure 110 was co-planar with the widest portion (at the surface 124) of the solder ball 120. Even without an overhang profile, it is noted that the profile of the mold structure side of the gap 130 is based on the original profile of the mold structure before the shape-altering operation, and thus would not be present in a configuration resulting from other gap-forming operations such as a laser ablation operation. It is also noted that in the example of FIG. 2B, the side portion 127 of the altered solder structure 120′ having a surface tension-induced profile would not be present in a configuration resulting from other gap-forming operations such as a laser ablation operation.

In the examples of FIGS. 1A and 1B, the solder balls 120 before the shape-altering operation have a shape based on a ball shape. However, it will be understood that in some embodiments, one or more features of the present disclosure can also be implemented with other solder structure shapes.

For example, FIG. 1C shows a solder structure 120 having a cross-sectional shape with a straight wall, such that the solder structure 120 has a cone shape. In some embodiments, such a shape can be achieved by use of a through mold via formed on a mold structure 110 followed by a solder filling operation. In some embodiments, such a shape can also be achieved by implementation of the solder structure 120 on a substrate 100 followed by formation of a mold structure 110. After formation of the solder structure 120 and the mold structure 110, materials can be removed to provide a flat surface configuration where an upper surface 114 of the mold structure 110 (when viewed as shown) and an exposed surface 124 of the solder structure 120 are substantially co-planar.

In another example, FIG. 1D shows a solder structure 120 having a cross-sectional shape with a straight wall, such that the solder structure 120 has a cylindrical shape. In some embodiments, such a shape can be achieved by implementation of the solder structure 120 on a substrate 100 followed by formation of a mold structure 110. After formation of the solder structure 120 and the mold structure 110, materials can be removed to provide a flat surface configuration where an upper surface 114 of the mold structure 110 (when viewed as shown) and an exposed surface 124 of the solder structure 120 are substantially co-planar.

For the solder structure examples of FIGS. 1C and 1D, FIGS. 2C and 2D show respective examples of altered solder structures 120′ relative to corresponding generally unchanged mold structures 110. For each of the examples of FIGS. 2C and 2D, in some embodiments, such an altered solder structure can result from melting of some or all of the respective original solder structure 120 so as to provide an altered shape. Such an altered shape can include a profile 128 having a side portion 127 and an upper portion 125 (when viewed as shown) resulting from the shape-altering operation (e.g., melting operation). In some embodiments, the altered profile 128 can be at least in part due to a surface tension of the solder material during the melting operation.

Configured in the foregoing manner, one can see that in each of the examples of FIGS. 2C and 2D, the altered solder structure 120′ provides a gap 130 between the side portion 127 of the altered solder structure 120′ and the inward-facing wall 116 of the mold structure 110. It is noted that the portion of the inward-facing wall 116 of the mold structure 110 defining the gap 130 does not include an overhang, since the inward-facing wall 116 is vertical or at an upwardly opening orientation. Even without an overhang profile, it is noted that the profile of the mold structure side of the gap 130 is based on the original profile of the mold structure before the shape-altering operation, and thus would not be present in a configuration resulting from other gap-forming operations such as a laser ablation operation. It is also noted that the side portion 127 of the altered solder structure 120′ having a surface tension-induced profile would not be present in a configuration resulting from other gap-forming operations such as a laser ablation operation.

FIG. 3 shows an enlarged view of an assembly that is similar to the assembly of FIG. 2A. In FIG. 3, the altered solder structure 120′ is shown to include a profile 128 having an upper portion 125 (when viewed as shown in FIG. 3) resulting from the shape-altering operation. The upper portion 125 is shown to rise above the upper surface 114 of the mold structure 110 by a height indicated as d2. In some embodiments, such a rise of the upper portion 125 can result when solder material is re-distributed during the shape-altering operation. For example, some or all of the solder material that was present in the gap 130 can provide the material in the raised shape of the upper portion 125.

In the example of FIG. 3, the mold structure 110 is depicted as having a thickness of d1. Configured in such a manner, the overall height of the assembly is d1+d2 over the surface 102 of the packaging substrate 100. In some embodiments, a packaged module can include and be utilized with the configuration of FIG. 3.

In some embodiments, at least some of the altered solder structure 120′ can be removed to reduce its height relative to the surface 114 of the mold structure 110.

For example, FIG. 4 shows a configuration where a portion of the altered solder structure 120′ has been removed to provide a new surface 132 that is still at height d3 above the upper surface 114 of the mold structure 110. In some embodiments, such a removal of material from the altered solder structure 120′ can be achieved by, for example, a grinding operation. Configured in such a manner, the overall height of the assembly of FIG. 4 is d1+d3 over the surface 102 of the packaging substrate 100. In some embodiments, a packaged module can include and be utilized with the configuration of FIG. 4.

In another example, FIG. 5 shows a configuration where a portion of the altered solder structure 120′ has been removed to provide a new surface 134 that is substantially co-planar (indicated as 136) with the upper surface 114 of the mold structure 110. In some embodiments, such a removal of material from the altered solder structure 120′ can be achieved by, for example, a grinding operation. Configured in such a manner, the overall height of the assembly of FIG. 5 is d1 over the surface 102 of the packaging substrate 100, since the surface 134 of the altered solder structure 120′ is substantially co-planar with the upper surface 114 of the mold structure 110. In some embodiments, a packaged module can include and be utilized with the configuration of FIG. 5.

FIG. 6 shows that in some embodiments, the thickness of the mold structure 110 can be changed to provide a desired thickness. For example, the original thickness d1 of the example configuration of FIG. 5 can be reduced to provide a thickness d4 that is less than d1. In some embodiments, such a reduced thickness (d4) can be utilized to contribute to a desired overall thickness of a packaged module having the configuration of FIG. 6.

In some embodiments, the reduced thickness d4 of the mold structure 110 can be achieved by, for example, a grinding operation to provide a new surface 118. In some embodiments, such a grinding operation can also remove a portion of the altered solder structure 120′ to provide a new surface 138, and such a new surface (138) of the altered solder structure 120′ can be substantially co-planar (indicated as 136) with the new surface 118 of the mold structure 110.

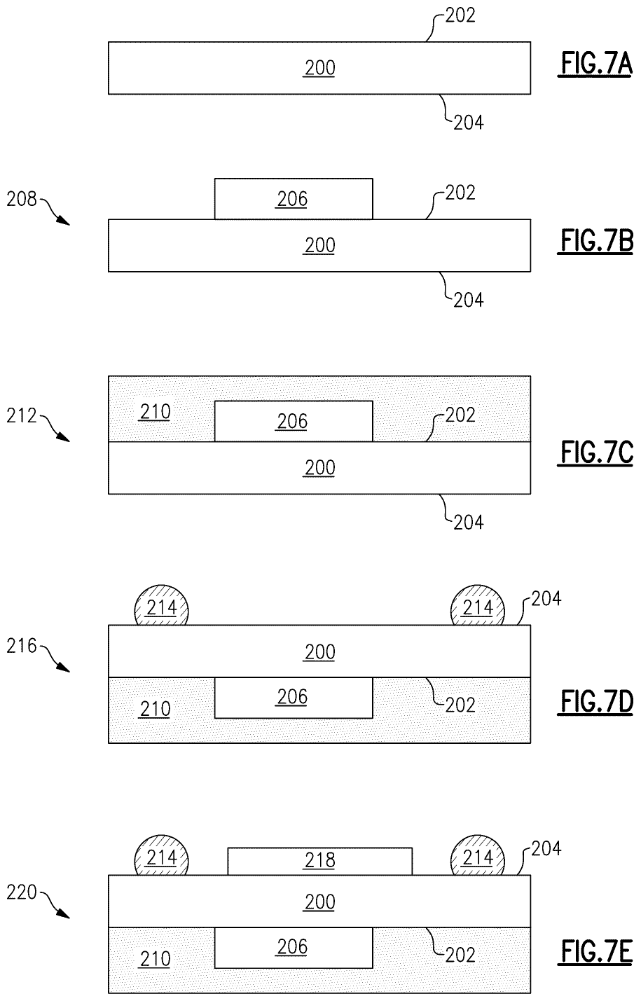

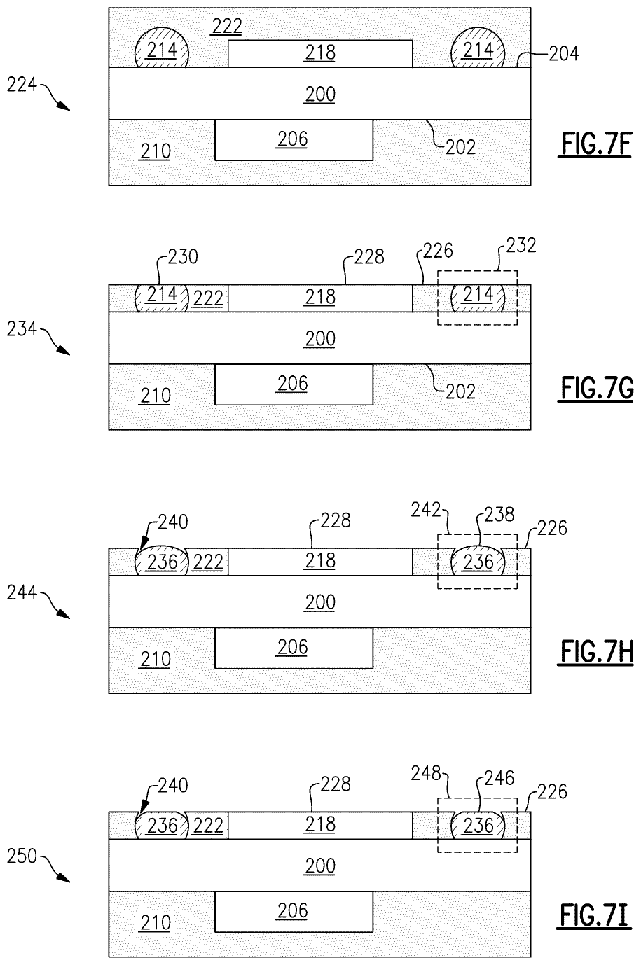

FIGS. 7A to 7I show various stages of a process that can be implemented to manufacture a packaged module having one or more features as described herein.

FIG. 7A shows a side view of a packaging substrate 200 having first and second sides 202, 204. For the purpose of description, the first side 202 can be utilized to form a non-mounting portion, and the second side 204 can be utilized to form a mounting portion. Accordingly, if the resulting packaged module is mounted on, for example, a circuit board in an orientation where the mounting portion is underneath the non-mounting portion, the first side 202 and second side 204 can be referred to herein as upper and lower sides, respectively, of the packaging substrate 200.

FIG. 7B shows an example stage where a component 206 is mounted onto the upper side 202 of the packaging substrate 200, so as to provide an assembly 208. Such a component can be, for example, a die or a passive device. It will be understood that more than one of such components can be mounted on the upper side 202 of the packaging substrate 200.

FIG. 7C shows an example stage where a mold structure 210 is formed over the upper side 202 of the packaging substrate 200, so as to provide an assembly 212. In some embodiments, such a mold structure (210) can be dimensioned to completely cover the component 206. In some embodiments, such a dimension of the mold structure 210 can include a height dimension between the upper side 202 of the packaging substrate 200 and the upper surface of the mold structure 210, and such a height can be the height in the completed packaged module, or be changed (e.g., reduced) to a desired height.

FIG. 7D shows an example stage where the assembly 212 of FIG. 7C is inverted, and a plurality of solder balls 214 are implemented on the lower side 204 of the packaging substrate 200, so as to provide an assembly 216. It will be understood that such solder balls are example shapes of conductive features; and such conductive features can also be implemented in different shapes.

FIG. 7E shows an example stage where a component 218 is mounted onto the lower side 204 of the packaging substrate 200, so as to provide an assembly 220. Such a component can be, for example, a die or a passive device. It will be understood that more than one of such components can be mounted on the lower side 204 of the packaging substrate 200.

FIG. 7F shows an example stage where a mold structure 222 is formed over the lower side 204 of the packaging substrate 200, so as to provide an assembly 224. In some embodiments, such a mold structure (222) can be dimensioned to completely cover the component 218 and the solder balls 214. Such a dimension of the mold structure 222 can include a height dimension between the lower side 204 of the packaging substrate 200 and a molded surface of the mold structure 222. In some embodiments, such a height can be reduced to a desired height to allow formation of a gap between each solder ball and the respective portion of the mold structure during a re-shaping process.

FIG. 7G shows an example stage where the thickness of the mold structure 222 is reduced to form a new surface 226, so as to provide an assembly 234. In some embodiments, such a thinning of the mold structure 222 can include a grinding operation.

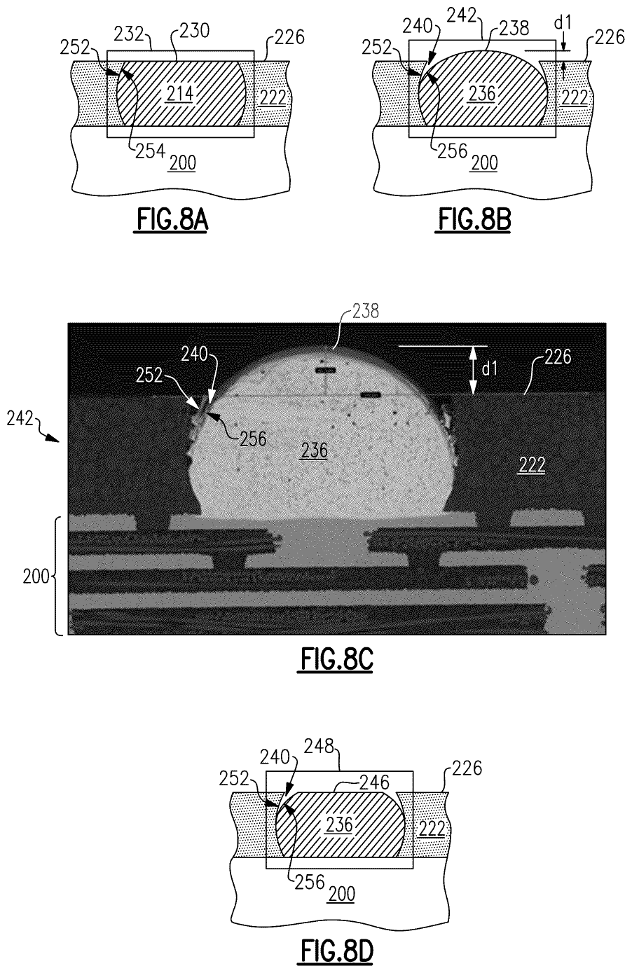

In some embodiments, and as described herein, the thinning operation of FIG. 7G can result in an exposed surface 230 for each solder ball, and such an exposed surface (230) of the solder ball 214 can be substantially co-planar with the new surface 226 of the reduced-height mold structure 222. An enlarged view of a portion indicated as 232 is shown in FIG. 8A.

In some embodiments, the thinning operation of FIG. 7G may or may not expose the back side (non-mounting side) of the component 218. For example, the thinning operation can result in the reduced-height mold structure 222 still covering all of the component 218. In another example, the thinning operation can result in the reduced-height mold structure 222 exposing some or all of the back side surface of the component 218. In yet another example, the thinning operation can result in a portion the of the back side of the component 218 also being removed (e.g., by a grinding operation) such that the new exposed surface of the back side of the component 218 is substantially co-planar with the new surface 226 of the reduced-height mold structure 222.

FIG. 7H shows an example stage where the solder balls 214 of FIG. 7G have undergone a re-shaping operation to form altered solder structures 236 each having an altered profile 238, so as to provide an assembly 244. As described herein, such a re-shaping operation can result in formation of a gap 240 between each altered solder structures 236 and the respective portion of the mold structure 222. An enlarged view of a portion indicated as 242 is shown in FIG. 8B. A sectional photograph of an enlarged view similar to that of FIG. 8B is shown in FIG. 8C.

In some embodiments, the mold structure 222 of FIGS. 7F to 7H can be formed from one or more materials to provide a melting temperature that is sufficiently higher than the melting temperature of the solder balls 214, such that when the solder balls 214 undergo a re-shaping operation including, for example, raising of temperature of the assembly 234 of FIG. 7G, the altered solder structures 236 of FIG. 7H are formed while the mold structure 222 retains its shape.

In some embodiments, and in the example context of solder balls 214 being formed from solder material, the re-shaping operation of FIG. 7H can include application of flux to the exposed surface (230 in FIG. 7G) of each solder ball 214. Then, a reflow or similar heating operation can be performed to allow some or all of each solder ball 214 to melt and be re-shaped, thereby generating a mold-to-solder separation as described herein.

FIG. 7I shows an example stage where respective raised portions (with respect to the surface 226 of the mold structure 222) of the altered solder structures 236 of FIG. 7H have been removed to provide a new surface 246 for each altered solder structure 236, so as to provide an assembly 250. As described herein, such removal of the raised portions of the altered solder structures 236 is shown to result in the gap 240 remaining between each altered solder structures 236 and the respective portion of the mold structure 222. An enlarged view of a portion indicated as 248 is shown in FIG. 8D.

In some embodiments, the assembly 250 of FIG. 7I can be a completed packaged module having one or more features as described herein. Thus, such a packaged module may also be indicated as 250. In some embodiments, such a packaged module may or may not be processed further. An example of the former (i.e., further-processed) is provided herein.

In some embodiments, and as described herein, the new surface 246 of each altered solder structure 236 in FIG. 7I can be substantially co-planar with the surface 226 of the mold structure 222. In some embodiments, the removal of the raised portions of the altered solder structures 236 can be achieved by, for example, a grinding operation. In some embodiments, such a grinding operation may or may not remove some of the mold structure 222.

As mentioned above, FIG. 8A shows an enlarged view of a portion 232 indicated in FIG. 7G where a thinning of a mold structure 222 results in an exposed surface 230 for each solder ball 214, with the exposed surface 230 of the solder ball 214 being substantially co-planar with a new surface 226 of the reduced-height mold structure 222. In such a configuration, surfaces 252 (of the mold structure 222) and 254 (of the solder ball 214) are shown to be in contact with each other without a gap therebetween.

As also mentioned above, FIG. 8B shows an enlarged view of a portion 242 indicated in FIG. 7H where an altered solder structure 236 has an altered profile 238 that results in a gap 240 between the surface 252 of the mold structure 222 and a surface 256 of an upper portion (when viewed as in FIG. 8B) of the altered profile 238 of the altered solder structure 236. In such a configuration, the altered profile 238 of the altered solder structure 236 is shown to have a height d1 with respect to the new surface 226 of the reduced-height mold structure 222.

As also mentioned above, FIG. 8C shows a sectional photograph of an enlarged view 242 that is similar to the enlarged view 242 of FIG. 8B. In FIG. 8C, the height d1 is indicated for the altered profile 238 of the altered solder structure 236, such that removal of the upper portion of the altered solder structure 236 corresponding to the height d1 can provide a configuration shown in FIG. 8D.

As also mentioned above, FIG. 8D shows an enlarged view of a portion 248 indicated in FIG. 7I where a portion of an altered solder structure 236 has been removed to provide a new surface 246 that can be substantially co-planar with the surface 226 of the mold structure 222. In such a configuration, the gap 240 between the surface 252 of the mold structure 222 and the surface 256 of the altered solder structure 236 is shown to be present, even with the foregoing removal of the portion of the altered solder structure 236.

In the configuration of FIG. 8D, the co-planar arrangement of the surface 246 of the altered solder structure 236 and the surface 226 of the mold structure 222 advantageously allows the resulting mounting surface to be a flat mounting surface with a desirable gap around each of altered solder structures.

FIGS. 7A to 7I show various stages of one module during its fabrication process. It will be understood that in some embodiments, some or all of such a fabrication process can be performed for multiple units in an array format.

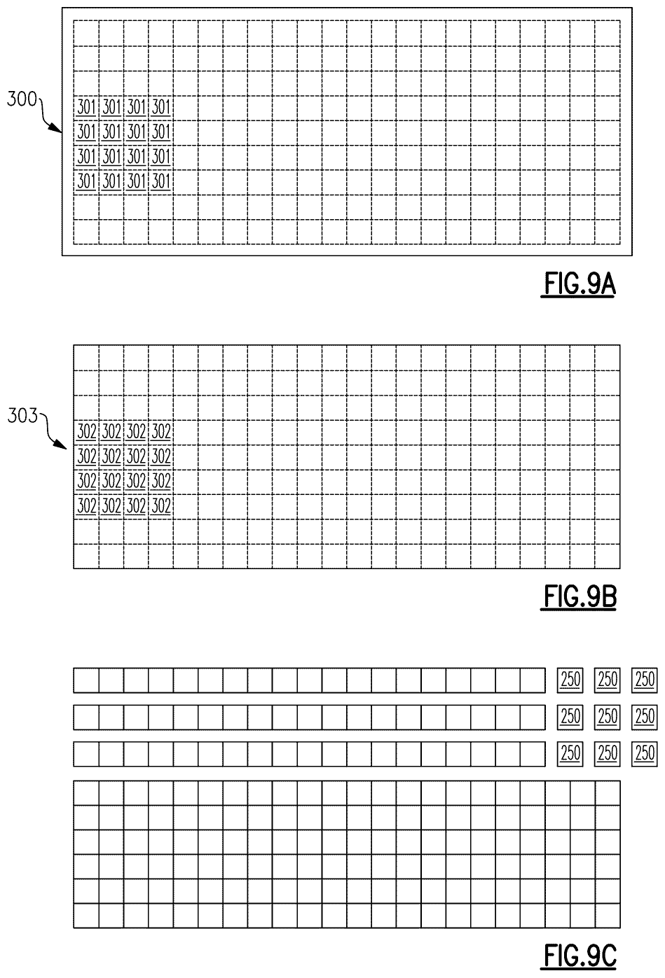

For example, FIGS. 9A to 9C show example stages of fabrication where multiple units are processed while in an array format and then singulated to provide multiple packaged units 250. More particularly, FIG. 9A shows a stage where a panel such as a substrate panel 300 is provided. Such a substrate panel can include an array of units 301, where each unit can be similar to, for example, the unit 200 described herein in reference to FIG. 7A.

FIG. 9B shows a stage where unit of FIG. 9A has been processed to provide respective processed units 302, so as to form an assembly 303. In FIG. 9B, each of such processed units (302) can be similar to, for example, the assembly 250 described herein in reference to FIG. 7I.

FIG. 9C shows a stage where the array of processed units 302 of FIG. 9B are being singulated to provide multiple packaged modules 250. As described herein, such packaged modules (250) may or may not be processed further.

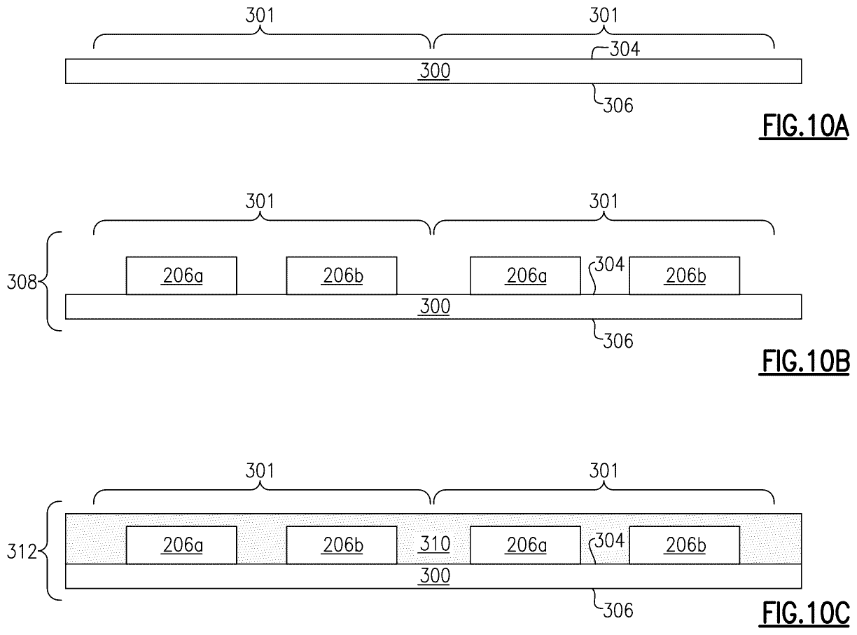

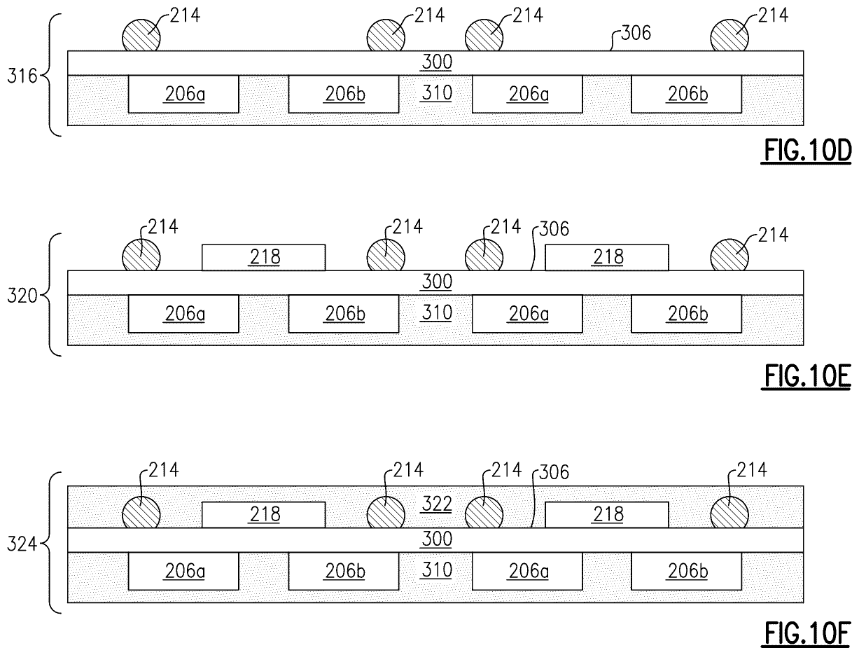

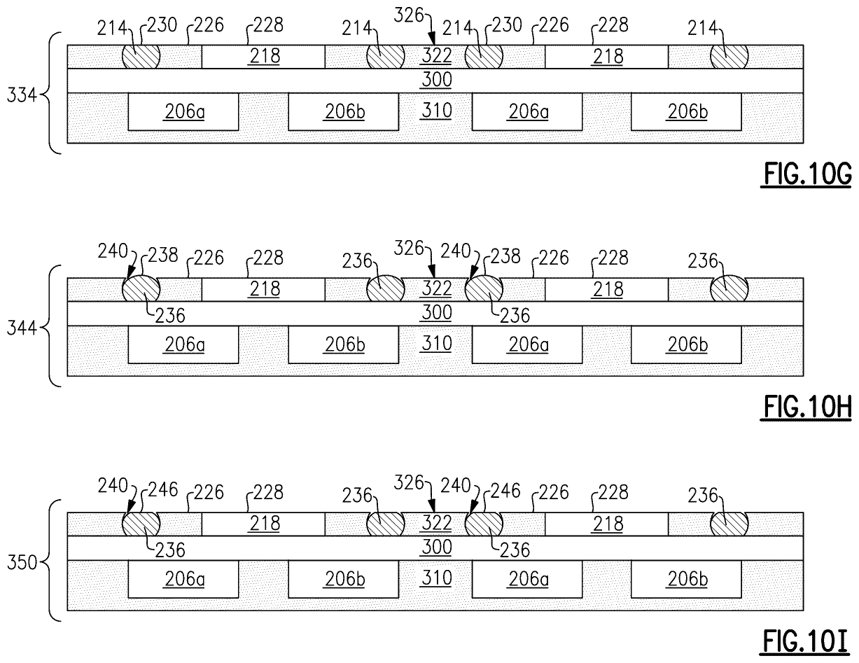

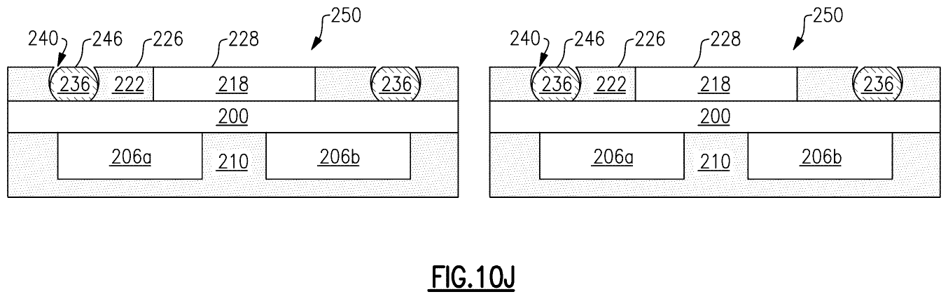

FIGS. 10A to 10I show side views of various stages of a process that can be utilized to form an array of process units in a panel format similar to the example of FIG. 9B, starting with a substrate panel similar to the example of FIG. 9A.

FIG. 10A shows a stage where a substrate panel 300 having first and second sides 304, 306 can be formed or provided. Such a substrate panel is shown to include an array of units 301, where each unit can be similar to, for example, the unit 200 described herein in reference to FIG. 7A.

FIG. 10B shows a stage where one or more components (e.g., die, passive device, etc.) can be mounted on the first side 304 of each unit 301 of the substrate panel 300, so as to provide an assembly 308. In the example of FIG. 10B, two of such components (indicated as 206a, 206b) are shown to be mounted on each unit; however, it will be understood that different number of component(s) can be utilized.

FIG. 10C shows a stage where a mold layer 310 is formed on the first side 304 of the substrate panel 300, so as to provide an assembly 312. Such a mold layer (310) is shown to form a mold structure on the first side 304 of each unit 301, similar to the mold structure 210 of FIG. 7C. It will be understood that the mold layer 310 that provides such mold structures for the array of units may be formed as a single contiguous mold structure, as individual mold structures for the respective units, or some combination thereof.

FIG. 10D shows a stage where a plurality of solder balls 214 are implemented for each unit on the second side 306 of the substrate panel 300, so as to provide an assembly 316. Similar to the example of FIG. 7D, it will be understood that such solder balls are example shapes of conductive features; and such conductive features can also be implemented in different shapes.

FIG. 10E shows a stage where one or more components (e.g., die, passive device, etc.) can be mounted on the second side 306 of each unit 301 of the substrate panel 300, so as to provide an assembly 320. In the example of FIG. 10E, one component (indicated as 218) is shown to be mounted on each unit; however, it will be understood that different number of components can be utilized.

FIG. 10F shows a stage where a mold layer 322 is formed on the second side 306 of the substrate panel 300, so as to provide an assembly 324. Such a mold layer (322) is shown to form a mold structure on the second side 306 of each unit 301, similar to the mold structure 222 of FIG. 7F. It will be understood that the mold layer 322 that provides such mold structures for the array of units may be formed as a single contiguous mold structure, as individual mold structures for the respective units, or some combination thereof.

FIG. 10G shows a stage where the thickness of the mold layer 322 is reduced to form a new surface 326, so as to provide an assembly 334. In some embodiments, such a thinning of the mold layer 322 can include a grinding operation.

In some embodiments, the thinning operation can result in the new surface 326 including an exposed surface 230 for each solder ball 214 and a new surface 226 of the reduced-height mold layer 322. In some embodiments, the foregoing exposed surface 230 of each solder ball 214 can be substantially co-planar with the new surface 226 of the reduced-height mold layer 322.

In some embodiments, the thinning operation of FIG. 10G may or may not expose the back sides (non-mounting side) of the components 218. For example, the thinning operation can result in the reduced-height mold layer 322 still covering all of the components 218. In another example, the thinning operation can result in the reduced-height mold layer 322 exposing some or all of the back side surfaces of the components 218. In yet another example, the thinning operation can result in portions the of the back sides of the components 218 also being removed (e.g., by a grinding operation) such that the new exposed surface of the back side of each component 218 is substantially co-planar with the new surface 226 of the reduced-height mold layer 322.

FIG. 10H shows a stage where the solder balls 214 of FIG. 10G have undergone a re-shaping operation to form altered solder structures 236 each having an altered profile 238, so as to provide an assembly 344. As described herein, such a re-shaping operation can result in formation of a gap 240 between each altered solder structures 236 and the respective portion of the mold layer 322.

In some embodiments, the mold layer 322 of FIGS. 10F to 10H can be formed from one or more materials to provide a melting temperature that is sufficiently higher than the melting temperature of the solder balls 214. Thus, when the solder balls 214 undergo a re-shaping operation including, for example, raising of temperature of the assembly 334 of FIG. 10G, the altered solder structures 236 of FIG. 10H are formed while the mold layer 322 retains its shape.

FIG. 10I shows an example stage where respective raised portions (with respect to the surface 226 of the mold layer 322) of the altered solder structures 236 of FIG. 10H have been removed to provide a new surface 246 for each altered solder structure 236, so as to provide an assembly 350. As described herein, such removal of the raised portions of the altered solder structures 236 is shown to result in the gap 240 remaining between each altered solder structures 236 and the respective portion of the mold layer 322.

In some embodiments, and as described herein, the new surface 246 of each altered solder structure 236 in FIG. 10I can be substantially co-planar with the surface 226 of the mold layer 322. In some embodiments, the removal of the raised portions of the altered solder structures 236 can be achieved by, for example, a grinding operation. In some embodiments, such a grinding operation may or may not remove some of the mold layer 322.

FIG. 10J shows that in some embodiments, the assembly 350 of FIG. 10I can be singulated to provide a plurality of individual units indicated as 250. In some embodiments, each of such individual units can be a packaged module similar to the example assembly 250 of FIG. 7I. In some embodiments, such a packaged module may or may not be processed further. An example of the former (i.e., further-processed) is provided herein.

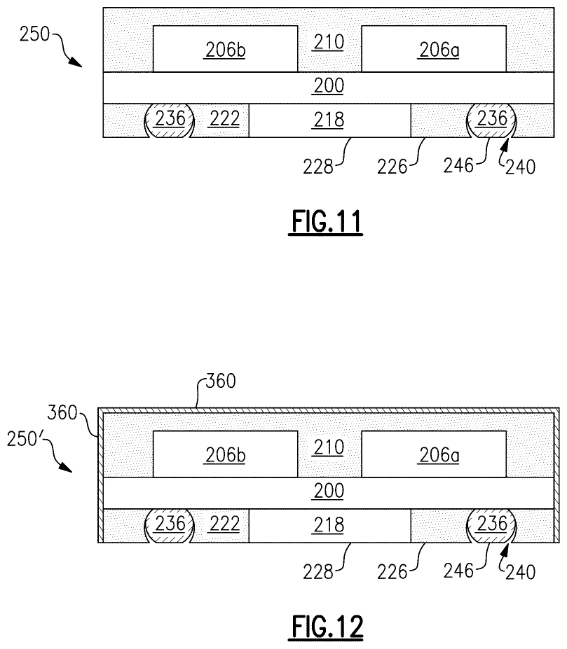

FIG. 11 shows a packaged module 250 having one or more features as described herein. Such a packaged module can be similar to the assembly 250 of FIG. 7I or an individual unit 250 of FIG. 10J resulting from singulation of an array format assembly. In some embodiments, such a package module can be utilized as is.

In some embodiments, the packaged module 250 of FIG. 11 can be processed further in its individual form. For example, FIG. 12 shows a packaged module 250′ that is similar to the packaged module 250 of FIG. 11. However, the packaged module 250′ of FIG. 12 is shown to further include a conformal shielding layer 360 formed from electrically conductive material that covers non-mounting sides of the packaged module 250′. For example, the upper side (when viewed as shown) and side walls of the packaged module 250′ can be covered with the conformal shielding layer 360. In some embodiments, such a conformal shielding layer can be electrically connected to an electrical ground plane within or on the packaging substrate 200. In some embodiments, such an electrical connection can be achieved through one or more of the side walls.

In some embodiments, one or more features as described herein can be implemented in a dual-sided mold grid array (DSMGA) module having a flat bottom. Such a flat-bottom module can be advantageous due to, for example, an ability to provide a desired height dimension by itself and when mounted onto a circuit board.

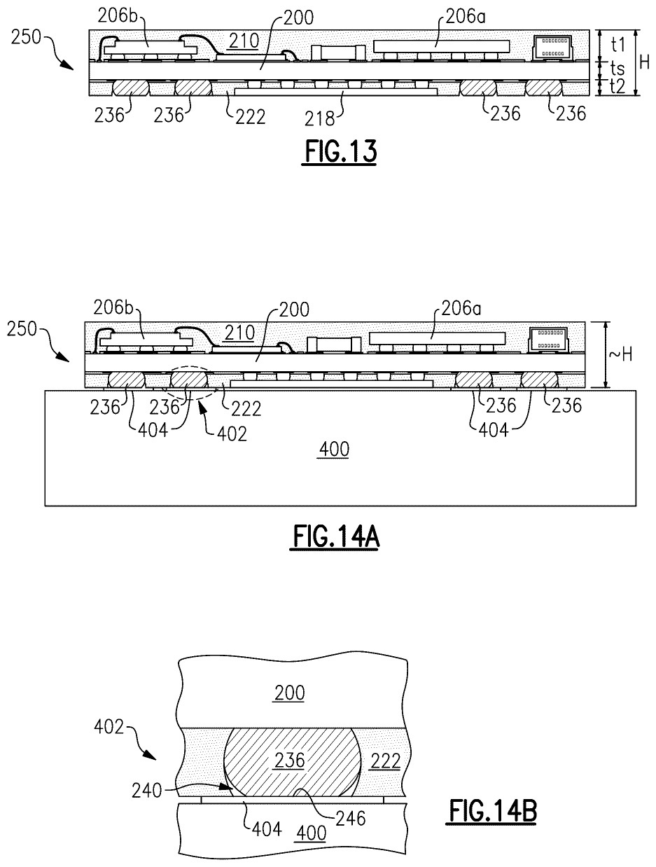

For example, FIG. 13 shows a flat-bottom module 250 having one or more features as described herein, similar to the examples of FIGS. 71, 11 and 12, where one or more components (e.g., 206a, 206b, etc.) is/are mounted on the upper side (when viewed as shown in FIG. 13) of a packaging substrate 200, and one or more components (e.g., 218) is/are mounted on the lower side of the packaging substrate 200. On the upper side of the packaging substrate 200, an upper mold structure 210 is provided, and on the lower side of the packaging substrate 200, a lower mold structure 222 is provided. The lower mold structure 222 is shown to laterally surround each altered solder structure 236, with the exposed surface of the altered solder structure 236 being substantially co-planar with the bottom surface of the lower mold structure 222, thereby providing a flat-bottom mounting configuration for the module 250.

Configured in the foregoing manner, the module 250 is shown to have an overall height of H which is approximately a sum of the thickness t1 of the upper mold structure 210, the thickness ts of the packaging substrate 200, and the thickness t2 of the lower mold structure 222. As described herein, such an overall height H of the module 250 can be desirably controlled by selecting some or all of the three thickness values t1, ts, t2.

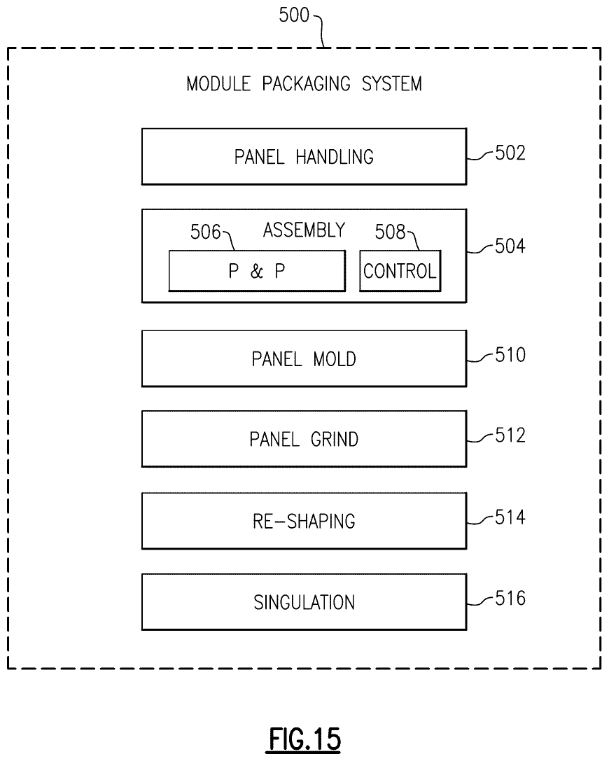

FIG. 14A shows a mounted configuration where the flat-bottom module 250 of FIG. 13 is mounted onto a circuit board 400 such as a circuit board associated with a wireless device. A portion indicated as 402 in FIG. 14A is also shown in an enlarged view in FIG. 14B.

Referring to FIGS. 14A and 14B, it is noted that when the flat-bottom module 250 is mounted on the circuit board 400, the flat exposed surfaces (246 in FIG. 14B) of the altered solder structures 236 are shown to be over respective contact pads 404 present on the mounting side of the circuit board 400. Such contact pads (404) can have a relatively small thickness value (e.g., compared to the overall thickness of the module 250), such that the height of the mounted module over the surface of the circuit board 400 is approximately H. Even if the contact pads have a significant thickness value, such a value can be known, so that the height of the mounted module over the surface of the circuit board 400 is known and controlled.

It is noted that a flat-bottom module with flat surfaces of solder structures and a flat surface of a mold structure can be secured to respective contact pads on a circuit board by, for example, solder joints. If such a flat-bottom module is configured such that there is no space between the solder structure and the surrounding mold structure, problematic issues such as solder joint voiding, bridging and/or shorting issues can arise.

However, and referring to FIGS. 14A and 14B, it is noted that when the flat exposed surfaces of the altered solder structures 236 are secured to the respective contact pads 404 of the circuit board 400 with, for example, solder joints, some or all of the foregoing soldering issues can be eliminated or reduced with the presence of the gap 240 as described herein. For example, such a gap can provide a space for receiving excess solder material that would otherwise cause some or all of the foregoing soldering issues.

FIG. 15 shows that in some embodiments, one or more features of the present disclosure can be implemented in a module packaging system 500. Such a system can include a number of systems, subsystems, apparatus, etc. configured to provide respective functionalities. For example, a panel handling component 502 can be provided to allow handling of carriers, substrate panels and/or panel assemblies having mold layer(s) thereon.

In another example, an assembly component 504 can be provided to, for example, mounting of devices on either or both sides of substrate panels, and formation of conductive features on the second side of substrate panels. In some embodiments, such an assembly functionality can be supported by, for example, a pick-and-place apparatus 506 in operation with a controller 508.

In yet another example, a panel mold component 510 can be provided to form some or all of panel mold layers as described herein. In some embodiments, such panel mold layer forming component can be configured to form first and second mold layers corresponding to first and second sides of dual-sided modules.

In yet another example, a panel grind component 512 can be provided to perform thinning operations on either or both of the first and second mold layers. In some embodiments, one or more thinning operations described herein can be achieved by the panel grind component 512.

In yet another example, a re-shaping component 514 can be provided to perform one or more operations to re-shape solder structures as described herein. In some embodiments, such a re-shaping component can include a heating component configured to melt solder material. In some embodiments, such a re-shaping component may be part of another component (e.g., assembly component 504), be a separate component, or some combination thereof.

In yet another example, a singulation component 516 can be provided to perform singulation operations on completed panel assemblies.

In some embodiments, some or all of the functional components of the module packaging system 500 of FIG. 15 can be performed under the control of, and/or facilitated by, a computer configured to execute one or more algorithms.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A packaged module comprising:
a substrate having a mounting side;
a plurality of solder structures implemented on the mounting side of the substrate, each solder structure having a shape that is different from its original shape when originally formed;
a mold structure implemented on the mounting side of the substrate and having a surface, such that each solder structure is surrounded by a respective portion of the mold structure having a shape formed based on the original shape of the solder structure, such that a gap is provided between the shape of the respective portion of the mold structure and the solder structure at or near the surface of the mold structure.

2. The packaged module of claim 1 further comprising a mold structure implemented on a non-mounting side of the substrate opposite from the mounting side.

3. The packaged module of claim 2 further comprising one or more components mounted on either or both of the non-mounting side and mounting side of the substrate.

4. The packaged module of claim 3 wherein at least some of the one or more components includes a die configured to provide radio-frequency functionality.

5. The packaged module of claim 4 wherein the die includes a semiconductor die.

6. The packaged module of claim 3 wherein at least one component is mounted on each of the non-mounting side and mounting side of the substrate.

7. The packaged module of claim 1 wherein the surface of the mold structure is flat.

8. The packaged module of claim 7 wherein the shape of each solder structure includes a profile at or near the surface of the mold structure, the profile resulting from a re-shaping operation that re-shapes the original shape of the solder structure to the shape while the solder structure is surrounded by the mold structure.

9. The packaged module of claim 8 wherein the re-shaping operation includes application of energy to melt some or all of the solder structure to allow the solder structure to be formed into the shape while the solder structure is surrounded by the mold structure.

10. The packaged module of claim 8 wherein each solder structure includes a flat surface at or near the flat surface of the mold structure, the flat surface of the solder structure resulting from removal of a portion of the profile of the solder structure.

11. The packaged module of claim 10 wherein the flat surface of the mold structure is substantially co-planar with the flat surface of the solder structure.

12. The packaged module of claim 11 wherein the flat surface of the mold structure and the flat surface of the solder structure are formed from a removal process that removes respective portions of the mold structure and solder structure.

13. The packaged module of claim 12 wherein the removal process includes a grinding process.

14. The packaged module of claim 8 wherein the solder structure has a melting point and the mold structure has a melting point that is higher than the melting point of the solder structure.

15. The packaged module of claim 1 wherein the original shape of the solder structure is based on formation without the presence of the mold structure, and the shape of the solder structure is based on formation with the presence of the mold structure.

16. The packaged module of claim 15 wherein the original shape of the solder structure includes a solder ball shape.

17. A method for manufacturing a packaged module, the method comprising:
providing or forming a substrate having a mounting side and a non-mounting side;
implementing a plurality of solder structures on the mounting side of the substrate such that each solder structure has an original shape;
processing the mounting side of the substrate, the processing including implementing a mold structure on the mounting side of the substrate such that the mold structure has a surface and an engagement shape around each solder structure based on the original shape of the solder structure, and such that the solder structure includes an exposed surface with respect to the surface of the mold structure; and
re-shaping each solder structure such that a gap is provided between the respective engagement shape of the mold structure and the re-shaped solder structure at or near the surface of the mold structure.

18. The method of claim 17 wherein the processing of the mounting side of the substrate further includes mounting one or more components on the mounting side of the substrate prior to the implementing of the mold structure.

19. The method of claim 17 further comprising processing the non-mounting side of the substrate, including mounting one or more components on the non-mounting side of the substrate and forming a mold structure on the non-mounting side of the substrate to encapsulate some or all of the one or more components.

20. The method of claim 17 wherein the surface of the mold structure is flat.

21. The method of claim 20 wherein the re-shaping includes applying energy to melt some or all of the solder structure while the solder structure is surrounded by the mold structure.

22. The method of claim 21 wherein the re-shaping further includes removing a portion of each solder structure to provide a flat surface for the re-shaped solder structure with respect to the flat surface of the mold structure.

23. The method of claim 22 wherein the flat surface of the mold structure is substantially co-planar with the flat surface of the re-shaped solder structure.

24. The method of claim 22 wherein the flat surface of the mold structure and the flat surface of the re-shaped solder structure are formed from a removal process that removes respective portions of the mold structure and re-shaped solder structure.

25. The method of claim 24 wherein the removal process includes a grinding process.

26. The method of claim 17 further comprising processing the non-mounting side of the substrate, including mounting one or more components on the non-mounting side of the substrate and implementing a mold structure on the non-mounting side of the substrate.

27. The method of claim 26 wherein the processing of the non-mounting side of the substrate is performed prior to the processing of the mounting side of the substrate.

28. The method of claim 26 wherein the substrate is a unit among a plurality of units arranged in an array format on a panel, such that some or all of the steps are performed for each unit while in the array format.

29. The method of claim 28 further comprising singulating the units in the array format to provide a plurality of singulated units.

30. The method of claim 29 further comprising forming a shielding layer to each of some or all of the singulated units.

31. A system for manufacturing packaged modules, the system comprising:
a panel handling component configured to handle a panel having an array of units, each unit having a substrate that includes a mounting side and a non-mounting side;
an assembly component configured to implement a plurality of solder structures on the mounting side of the substrate of each unit such that each solder structure has an original shape;
one or more components for processing the mounting side of the substrate, the processing including implementing a mold structure on the mounting side of the substrate of each unit such that the mold structure has a surface and an engagement shape around each solder structure based on the original shape of the solder structure, and such that the solder structure includes an exposed surface with respect to the surface of the mold structure; and
a re-shaping component configured to re-shape each solder structure such that a gap is provided between the respective engagement shape of the mold structure and the re-shaped solder structure at or near the surface of the mold structure.

32. The system of claim 31 further comprising a singulation component configured to singulate an assembly resulting from the process operations into a plurality of individual packaged modules.

33. The system of claim 32 further comprising a deposition component configured to form a shielding layer to each individual packaged module.

34. The system of claim 31 wherein the one or more components includes a panel mold component configured to form the mold structure on the mounting side of the substrate of each unit.

35. The system of claim 34 wherein the one or more components further includes a panel grind component configured to form the surface of the mold structure and to provide the exposed surface of the solder structure with respect to the surface of the mold structure.

36. The system of claim 31 wherein the re-shaping component is configured to provide energy to the solder structures of each unit to sufficiently melt to form the respective re-shaped solder structures.

37. The system of claim 36 wherein the energy provided to the solder structures includes heat.
